(19) United States
(12) Patent Application Publication
(10) Pub. No.: US 2016/0372514 A1
(43) Pub. Date: Dec. 22, 2016

(54) LIGHT EMITTING DIODE DISPLAY AND MANUFACTURING METHOD THEREOF

(71) Applicant: AU Optronics Corporation, HSIN-CHU (TW)

(72) Inventors: Cheng-Chieh CHANG, HSIN-CHU (TW); Tsung-Tien WU, HSIN-CHU (TW); Kang-Hung LIU, HSIN-CHU (TW); Hsiang-Yun HSIAO, HSIN-CHU (TW)

(21) Appl. No.: 15/158,725

(22) Filed: May 19, 2016

(30) Foreign Application Priority Data
Jun. 16, 2015 (TW) 104119432

(51) Int. Cl. H01L 27/15; H01L 27/12

(52) U.S. Cl. CPC H01L 27/156; H01L 27/1259

(57) ABSTRACT

An LED display is provided in considering of both the human eye perception and inconsistent luminous efficiencies of LEDs in a red, blue, and green sub-pixels. A total area of a light-exiting surface of a red micro LED is larger than a total area of a light-exiting surface of a green micro LED so as to improve the problem that the sub-pixels of different colors have inconsistent luminous efficiencies.

### RELATED APPLICATIONS

This application claims priority to Taiwan Application Serial Number 104119432, filed Jun. 16, 2015, which is herein incorporated by reference.

### BACKGROUND

Field of Disclosure

The present disclosure relates to a display. More particularly, the disclosure relates to a light emitting diode (LED) display and a manufacturing method thereof.

Background of the Disclosure

With the progress of technology, displays have gradually changed from the bulky cathode ray tube (CRT) displays to the flat, lightweight and slim liquid crystal displays (LCDs), plasma display panels (PDPs), or organic light emitting diode (OLED) displays, etc.

The OLED displays, as compared with the LCDs, do not need color filters as required by traditional LCD displays, thus having a simpler structure and smaller volume. In addition to that, OLEDs can be fabricated on flexible substrates, such that the OLED displays are not only lightweight and slim but also bendable. Therefore, the development and research of OLED displays have become one of the important subjects in the market. However, the OLED displays have a low blue luminous efficiency, and the organic light emitting materials have the stability problem which are the major problems faced in mass production.

### SUMMARY

The disclosure relates to a light emitting diode (LED) widely applied to lighting equipment. A side length of the LED is shrunk to 3 micrometers to 150 micrometers so as to be fabricated on a substrate, or 3 micrometers to 100 micrometers so as to form an LED display.

Full-color LED displays can utilize shrunk LEDs to constitute red sub-pixel, green sub-pixels, and blue sub-pixels without disposing color filters required by traditional LCD displays. However, after LEDs are shrunk down to a micrometer scale, the luminous efficiencies of the LEDs of different colors are not consistent. In addition, human eyes have different perception to light in different wave bands. Hence, users may find that light in some wave band is too bright and light in some other wave band is too dark, thus hindering the development of LED displays.

One aspect of the disclosure is to provide an LED display.

The LED display comprises at least one pixel unit. The pixel unit has a plurality of sub-pixels disposed on a substrate. The plurality of sub-pixels comprises a red sub-pixel, a green sub-pixel, and a blue sub-pixel. The red sub-pixel comprises at least one red micro LED. The green sub-pixel comprises at least one green micro LED. The blue sub-pixel comprises at least one blue micro LED. The red sub-pixel, the green sub-pixel, and the blue sub-pixel are located in the pixel unit. In an independent pixel unit, each of the red micro LED, the green micro LED, and the blue micro LED comprises a first type semiconductor layer, a second type semiconductor layer, an active layer disposed between the first type semiconductor layer and the second type semiconductor layer, and two electrodes. Each of the at least one red micro LED, the at least one green micro LED, and the at least one blue micro LED has a light-exiting surface. A total area of the light-exiting surface of the at least one red micro LED is larger than a total area of the light-exiting surface of the at least one green micro LED. The two electrodes are disposed in each of the red sub-pixel, the green sub-pixel, and the blue sub-pixel. One of the two electrodes is electrically connected with the corresponding first type semiconductor layer. The other one of the two electrodes is electrically connected with the second type semiconductor layer. At least one of the two electrodes is electronically connected with a corresponding thin film transistor.

The disclosure further provides an LED display. The LED display comprises a pixel unit, a first sub-pixel, and a second sub-pixel. The pixel unit is disposed on a substrate. The first sub-pixel comprises at least one first micro LED. The second sub-pixel comprises at least one second micro LED. The first sub-pixel and the second sub-pixel are located in the pixel unit. The first micro LED has a first light-exiting surface corresponding to the first micro LED. The second micro LED has a second light-exiting surface corresponding to the second micro LED. An area of the first light-exiting surface is not equal to an area of the second light-exiting surface.

The disclosure further provides a manufacturing method of an LED display.

The manufacturing method of the LED display comprises the following steps: providing a substrate, wherein the substrate comprises at least one pixel unit; transferring at least one red micro LED from an another substrate to the substrate, and disposing the at least one red micro LED in the pixel unit to form a red sub-pixel; transferring at least one green micro LED from the another substrate to the substrate, and disposing the at least one green micro LED in the pixel unit to form a green sub-pixel; and transferring at least one blue micro LED from the another substrate to the substrate, and disposing the at least one blue micro LED in the pixel unit to form a blue sub-pixel. The red sub-pixel, the green sub-pixel, and the blue sub-pixel are located in the pixel unit. A total area of a light-exiting surface of the red micro LED is larger than a total area of a light-exiting surface of the green micro LED.

Since the red micro LED has an inferior luminous efficiency to the green micro LED, the total area of the light-exiting surfaces of the red micro LEDs is larger than the total area of the light-exiting surfaces of the green micro LEDs to improve the inferior luminous efficiency of the red micro LED according to the embodiments of the disclosure. In addition, as compared with green light, human eyes are less sensitive to red light. Hence, when the total area of the light-exiting surfaces of the red micro LEDs are larger, the problem that human eyes are not easy to perceive red light can be improved so as to improve the inconsistent luminous efficiencies of sub-pixels of different colors.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 depicts a schematic diagram of a red sub-pixel, a green sub-pixel, and a blue sub-pixel in an individual pixel unit of an LED display;

FIG. 2 depicts a relational graph between external quantum efficiencies of a red micro LED, a green micro LED, and a blue micro LED and current densities;

FIG. 3 depicts a schematic diagram of an LED display according to one embodiment of this disclosure;

FIG. 4 depicts a cross-sectional view taken along line 4 in FIG. 3;

FIG. 5 depicts a cross-sectional view of an LED display according to another embodiment of this disclosure;

FIG. 6 depicts an enlarged view of a pixel unit of an LED display according to one embodiment of this disclosure;

FIG. 7 depicts a curve illustrating human eye perception to light in different wave bands;

FIG. 8 depicts an enlarged view of a pixel unit of an LED display according to another embodiment of this disclosure; and

FIG. 9 depicts an enlarged view of a pixel unit of an LED display according to still another embodiment of this disclosure.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In addition, drawings are only for the purpose of illustration and not plotted according to the original size. Wherever possible, the same reference numbers are used in the drawings and the description to refer to the same or like parts.

As used herein, “substantially”, “around,” “about” or “approximately” shall generally mean within 20 percent, preferably within 10 percent, and more preferably within 5 percent of a given value or range. Numerical quantities given herein are approximate, meaning that the term “substantially”, “around,” “about” or “approximately” can be inferred if not expressly stated.

In the following embodiments, a light emitting diode (LED) display comprises a plurality of pixel units. A single pixel unit may comprise a plurality of sub-pixels (such as a red sub-pixel, a green sub-pixel, and a blue sub-pixel, or a first sub-pixel, a second sub-pixel, and a third sub-pixel). A single sub-pixel may comprise one or more single color micro LEDs (for example: the red sub-pixel may comprise one or more red micro LEDs, and so do the green sub-pixel and the blue sub-pixel. A size of micro LEDs is on a scale of micrometers. In greater detail, a side length of micro LEDs is from 3 micrometers to 150 micrometers, but the disclosure is not limited in this regard. In addition, in the following embodiments, a “total area” of light-exiting surfaces of micro LEDs refers to a sum of areas of light-exiting surfaces of one or more micro LEDs in each sub-pixel. That is, if the sub-pixel only has a single micro LED, the “total area” refers to an area of the light-exiting surface of the single micro LED in the sub-pixel. If the sub-pixel has a plurality of micro LEDs, the “total area” refers to the sum of the areas of the light-exiting surfaces of all the micro LEDs in the sub-pixel.

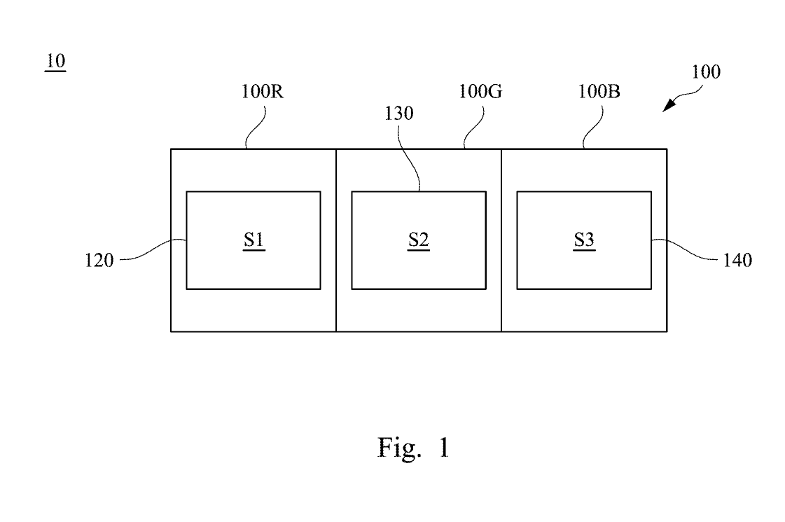

It is noted that luminous efficiencies of the red micro LED in the red sub-pixel, the green micro LED in the green sub-pixel, and the blue micro LED in the blue sub-pixel are not the same. Preferably, the micro LEDs are inorganic LEDs having a scale less than or substantially equal to micrometers. A description is provided with reference to FIG. 1. FIG. 1 depicts a schematic diagram of a red sub-pixel 100R, a green sub-pixel 100G, and a blue sub-pixel 100B in an individual pixel unit 100 of an LED display 10. In greater detail, a total area of a light-exiting surface S1 of a red micro LED 120, a total area of a light-exiting surface S2 of a green micro LED 130, and a total area of a light-exiting surface S3 of a blue micro LED 140 are substantially the same as shown in FIG. 1. Under the circumstances, if luminous efficiencies of the red micro LED 120, the green micro LED 130, and the blue micro LED 140 are not consistent, color performance of the LED display 10 will be impacted.

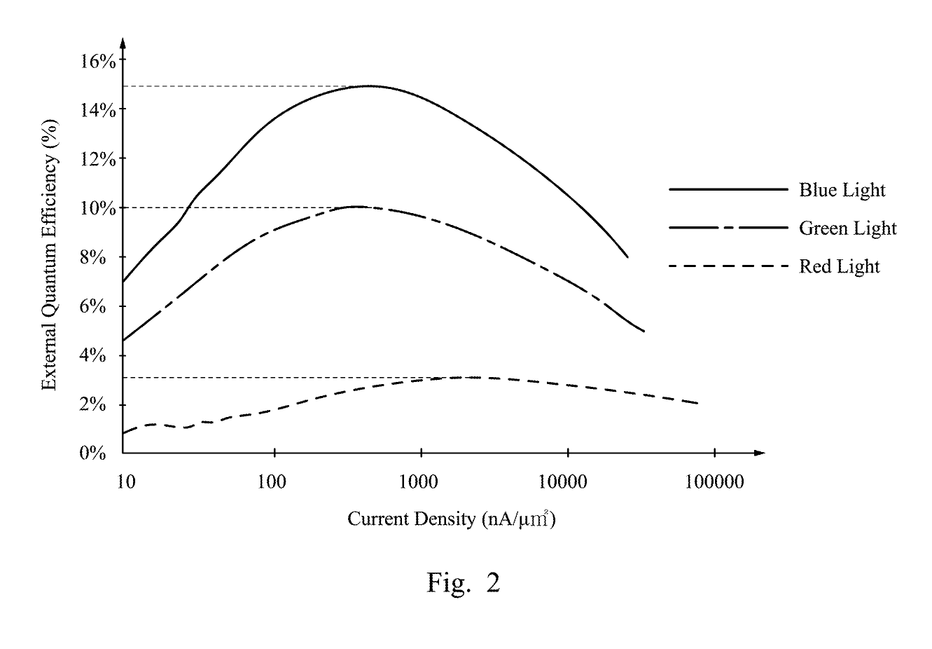

In greater detail, a description is provided with reference to FIG. 1 and FIG. 2. FIG. 2 depicts a relational graph between external quantum efficiencies of the red micro LED 120, the green micro LED 130, and the blue micro LED 140 and current densities, where the horizontal axis represents current density with the unit nA/μm², the vertical axis represents external quantum efficiency (EQE). As shown in FIG. 2, if an area of the light-exiting surface of the red micro LED 120, an area of the light-exiting surface of the green micro LED 130, and an area of the light-exiting surface of the blue micro LED are all 100 μm², highest EQEs of the red micro LED 120, the green micro LED 130, and the blue micro LED 140 are approximately 3%, 10%, and 15%, respectively, when the red micro LED 120, the green micro LED 130, and the blue micro LED 140 have different current densities. Under the circumstances, even though the red micro LED 120, the green micro LED 130, and the blue micro LED 140 can respectively receive currents having different magnitudes, the inferior luminous efficiency of the red sub-pixel 100R is difficult to improve.

In view of this, the embodiments according to the disclosure provide an LED display that is able to improve the inferior luminous efficiency of the red sub-pixel 100R. In greater detail, by adjusting magnitude relationships between the total area of the light-exiting surface of the red micro LED 120 in the red sub-pixel 100R and total areas of light-exiting surfaces of micro LEDs in sub-pixels of the other colors, the inconsistent luminous efficiencies of micro LEDs of different colors in the LED display are thus improved. A detailed description is provided as follows.

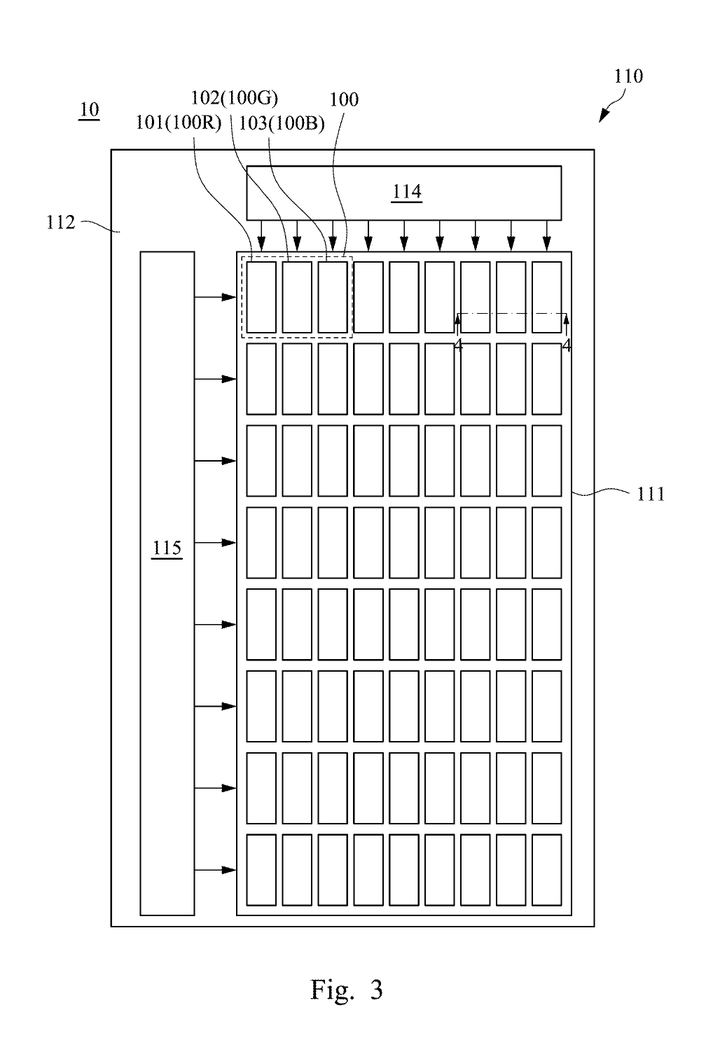

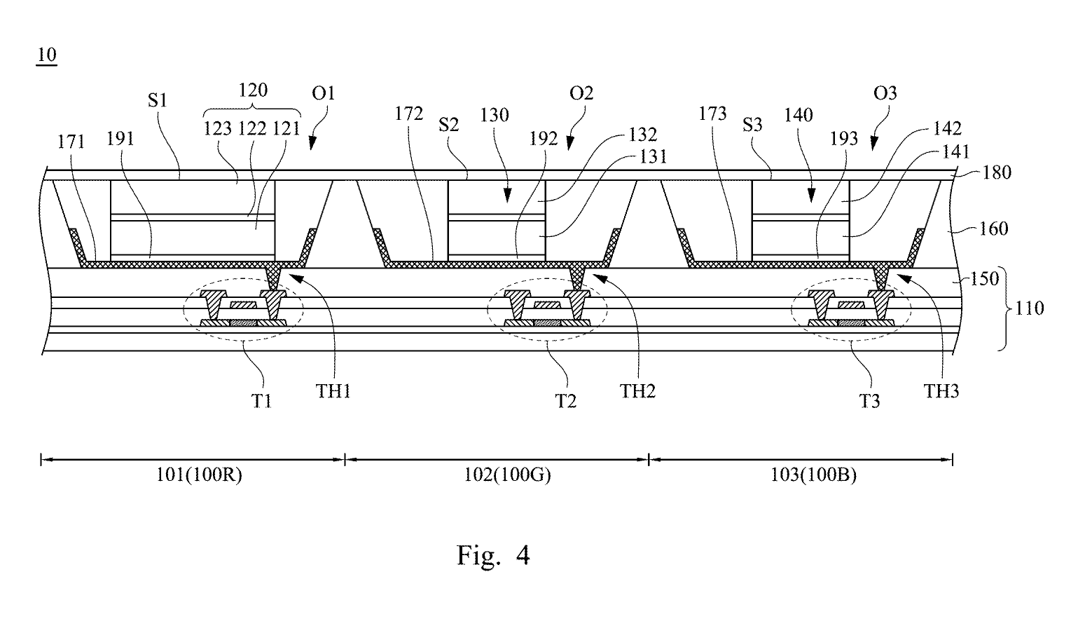

First, a description is provided with reference to FIG. 3 and FIG. 4. FIG. 3 depicts a schematic diagram of the LED display 10 according to one embodiment of this invention. FIG. 4 depicts a cross-sectional view taken along line 4 in FIG. 3. As shown in FIG. 3, the LED display 10 comprises the plurality of pixel units 100, first sub-pixels 101, second sub-pixels 102, and third sub-pixels 103. The pixel units 100 are disposed on a substrate 110. The substrate 110 comprises a display area 111 and a non-display area 112. The pixel units 100 are located in the display area 111, and the first sub-pixels 101, the second sub-pixels 102, and the third sub-pixels 103 are located in the pixel units 100. Each of the pixel units 100 occupies approximately a same area as an example. That is, each of the pixel units 100 in the display area 111 has approximately the same area. In addition, the first sub-pixel 101, the second sub-pixel 102, and the third sub-pixel 103 comprised in each of the pixel units 100 may, for example, respectively be the red sub-pixel 100R, the green sub-pixel 100G, and the blue sub-pixel 100B, but the disclosure is not limited in this regard. Additionally, each of the sub-pixels may comprise at least one micro LED. For example, the first sub-pixel 101 may comprise at least one first micro LED (such as the red micro LED 120), the second sub-pixel 102 may comprise at least one second micro LED (such as the green micro LED 130), the third sub-pixel 103 may comprise at least one third micro LED (such as the blue micro LED 140).

For example, the red micro LED 120 may be configured to from the red sub-pixel 100R, the green micro LED 130 may be configured to from the green sub-pixel 100G, and the blue micro LED 140 may be configured to from the blue sub-pixel 100B. The red sub-pixel 100R, the green sub-pixel 100G, and the blue sub-pixel 100B are located in the pixel unit 100. The non-display area 112 may comprise a data line driving circuit 114 and a scan line driving circuit 115. The data line driving circuit 114 is connected to data lines of the red sub-pixels 100R, the green sub-pixels 100G, and the blue sub-pixels 100B so as to transmit data signals to each of the sub-pixels. The scan line driving circuit 115 is connected to scan lines of the red sub-pixels 100R, the green sub-pixels 100G, and the blue sub-pixels 100B so as to transmit scan signals to each of the sub-pixel.

In the embodiment shown in FIG. 4, the first sub-pixel 101 (that is, the red sub-pixel 100R) may comprise the red micro LED 120, the second sub-pixel 102 (that is, the green sub-pixel 100G) may comprise the green micro LED 130, and the third sub-pixel 103 (that is, the blue sub-pixel 100B) may comprise the blue micro LED 140 in the pixel unit 100. Through combining lights emitted from the red sub-pixel, the green sub-pixel, and the blue sub-pixel, the LED display 10 is allowed to emit full-color images.

With additional reference to FIG. 3 and FIG. 4, the substrate 110 of the LED display 10 may be an active device array substrate. Two electrodes (at least one first electrode 171, 172, 173 and at least one second electrode 180) are disposed in each of the red sub-pixel 100R, the green sub-pixel 100G, and the blue sub-pixel 100B, wherein one of the two electrodes is electrically connected with the corresponding first type semiconductor layer 121, the other one of the two electrodes is electrically connected with the second type semiconductor layer 123, and at least one of the two electrodes is electronically connected with a corresponding thin film transistor. In greater detail, the substrate 110 comprises a plurality of pixel circuits T1, T2, T3, an insulating layer 150, a pixel define layer 160, at least one first electrode 171, 172, 173 and at least one second electrode 180. The plurality of pixel circuits T1, T2, T3 are respectively located in the red sub-pixel 100R, the green sub-pixel 100G, and the blue sub-pixel 100B corresponding to the plurality of pixel circuits T1, T2, T3, and configured to respectively drive the red micro LED 120, the green micro LED 130, and the blue micro LED 140. In one embodiment, each of the pixel circuits T1, T2, T3 may further comprise at least one thin film transistor. The insulating layer 150 covers the pixel circuits T1, T2, T3. The pixel define layer 160 is on top of the insulating layer 150, and the pixel define layer 160 comprises a plurality of openings O1, O2, and O3 in it. In the present embodiment, the red micro LED 120 is located in the opening O1, the green micro LED 130 is located in the opening O2, and the blue micro LED 140 is located in the opening O3. The first electrodes 171, 172, 173 may be respectively located in the openings O1, O2, O3, and the three first electrodes 171, 172, 173 are electrically connected to the pixel circuits T1, T2, T3, respectively. In one embodiment, each of the first electrodes 171, 172, 173 may comprise a non-transparent conductive material, such as silver, aluminum, copper, magnesium, or molybdenum, a transparent conductive material, such as indium tin oxide, indium zinc oxide, or zinc aluminum oxide, a composite layer thereof, or an alloy thereof, but the disclosure is not limited in this regard. Not only do the first electrodes 171, 172, 173 have a good electrical conductivity, but the first electrodes 171, 172, 173 are also light reflective.

In greater detail, the insulating layer 150 may have a plurality of through holes TH1, TH2, TH3 in it to expose part of the pixel circuits T1, T2, T3. The openings O1, O2, O3 in the pixel define layer 160 can respectively expose the through holes TH1, TH2, TH3. When the first electrodes 171, 172, 173 are formed in the openings O1, O2, O3, the first electrodes 171, 172, 173 may be electrically connected to the pixel circuits T1, T2, T3 via the through holes TH1, TH2, TH3. Additionally, the three first electrodes 171, 172, 173 may be electrically connected to one terminal of the red micro LED 120, one terminal of the green micro LED 130, and one terminal of the blue micro LED 140, respectively. The second electrode 180 is electrically connected to another terminal of the red micro LED 120, another terminal of the green micro LED 130, and another terminal of the blue micro LED 140. According to the present embodiment, the second electrode 180 may serve as a common electrode.

In addition, in each of the pixel units 100, each of the red micro LED 120, the green micro LED 130, and the blue micro LED 140 may comprise a first type semiconductor layer 121, an active layer 122, and a second type semiconductor layer 123 (although in the figure only the red micro LED 120 is shown, it would be understood that the green micro LED 130 and the blue micro LED 140 have the same structure). The active layer 122 is disposed between the first type semiconductor layer 121 and the second type semiconductor layer 123. For example, the active layer 122 is disposed on the first type semiconductor layer 121. The second type semiconductor layer 123 is disposed on the active layer 122. For example, a first type semiconductor layer 121 of the red micro LED 120 may be the P-type semiconductor or the N-type semiconductor. The second type semiconductor layer 123 of the red micro LED 120 may be the P-type semiconductor or the N-type semiconductor. The P-type semiconductor or the N-type semiconductor may be gallium arsenide (GaAs) or other suitable materials. First type semiconductor layers 131, 141 of the green micro LED 130 and the blue micro LED 140 may be the P-type semiconductor or the N-type semiconductor. Second type semiconductor layers 132, 142 of the green micro LED 130 and the blue micro LED 140 may be the P-type semiconductor or the N-type semiconductor. The P-type semiconductor and the N-type semiconductor may be gallium nitride (GaN), zinc selenide (ZnSe), or aluminum nitride (AlN), or other suitable materials. A material of the active layer 120 may be gallium nitride or indium gallium nitride (InGaN), or other suitable materials.

In addition to that, each of the red micro LED 120, the green micro LED 130, and the blue micro LED 140 has the light-exiting surface S1, for example. The second type semiconductor layer 123 has the light-exiting surface S1 on a surface opposite to the active layer 122. Similarly, the second type semiconductor layers of the green micro LED 130 and the blue micro LED 140 respectively have the light-exiting surfaces S2, S3 too. According to the present embodiment, the first micro LED in the first sub-pixel 101 has a first light-exiting surface corresponding to the first micro LED. The second micro LED in the second sub-pixel 102 has a second light-exiting surface corresponding to the second micro LED. An area of the first light-exiting surface is not equal to an area of the second light-exiting surface. In greater detail, the total area of the light-exiting surface S1 of the red micro LED 120 in the red sub-pixel 100R is larger than the total area of the light-exiting surface S2 of the green micro LED 130 in the green sub-pixel 100G. Since the total area of the light-exiting surface S1 of the red micro LED 120 is larger than the total area of the light-exiting surface S2 of the green micro LED 130, the inferior luminous efficiency of the red sub-pixel 100R is able to be compensated.

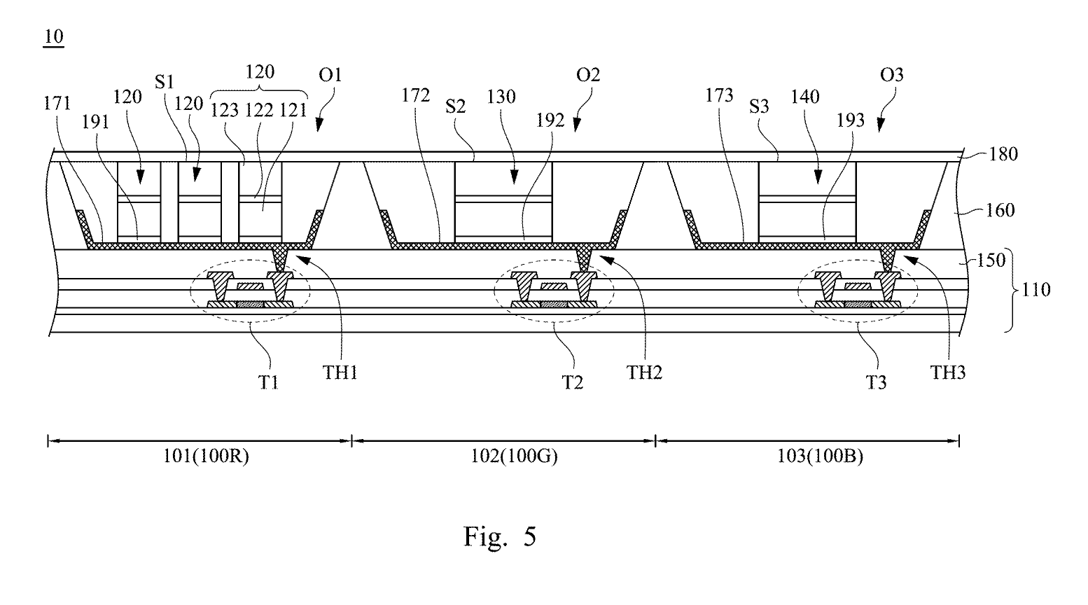

FIG. 5 depicts a cross-sectional view of the LED display 10 according to another embodiment of this invention. The cross-sectional position of FIG. 5 is the same as that of FIG. 4. The difference between the present embodiment and the embodiment in FIG. 4 lies in that a number of the red micro LEDs 120 is plural in the present embodiment pixel unit 100. In greater detail, it would be understood from the embodiment shown in FIG. 5 that those of ordinary skill in the art may select disposing the red micro LED in a larger size or select disposing the plurality of red micro LEDs in a smaller size, so that a sum of areas of the light-exiting surfaces S1 of the red micro LEDs 120 is larger than a sum of an area of the light-exiting surface S2 of the green micro LED 130. For example, one micro LED having an area of a light-exiting surface of about 100 μm² is equivalent to ten micro LEDs having an area of a light-exiting surface of about 10 μm². Hence, since a total area of the light-exiting surfaces S1 of the plurality of red micro LED 120 is larger than a total area of the light-exiting surface S2 of the at least one green micro LED 130, the inferior luminous efficiency of the red sub-pixel 100R is able to be compensated. Because the sub-pixel has a plurality of micro LEDs of the same color, the current loaded by the micro LED is less than that loaded by the single LED in the sub-pixel, the damage of the micro LED caused by an overcurrent is thus avoided to elongate the lifetime of the LED display 10. In addition, when part of the plurality of micro LEDs of the same color in the sub-pixel are damaged, dark spots in the sub-pixel are not generated in a bright state.

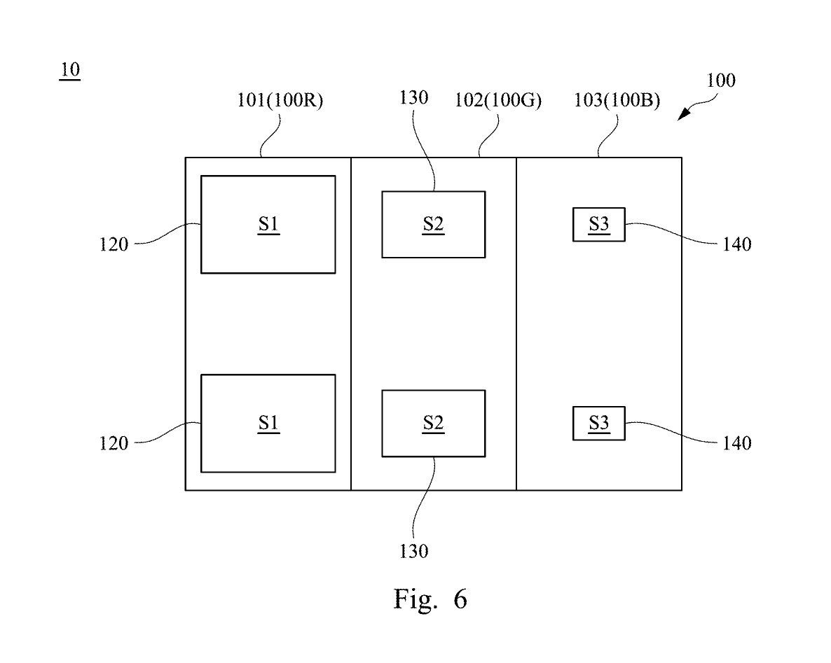

FIG. 6 depicts an enlarged view of the pixel unit 100 of the LED display 10 according to one embodiment of this invention. In the embodiment shown in FIG. 6, the first sub-pixel 101 (that is, the red sub-pixel 100R) comprises the two red micro LEDs 120, the second sub-pixel 102 (that is, the green sub-pixel 100G) comprises the two green micro LEDs 130, and the third sub-pixel 103 (that is, the blue sub-pixel 100B) comprises the two blue micro LEDs 140. In the present embodiment, magnitude relationships between the total areas of the micro LEDs of different colors are adjusted in consideration of the different luminous efficiencies of the micro LEDs of different colors. In the pixel unit 100 according to the present embodiment, the second micro LED in the second sub-pixel 102 has the second light-exiting surface corresponding to the second micro LED, the third micro LED in the third sub-pixel 103 has the third light-exiting surface corresponding to the third micro LED, and the area of the second light-exiting surface is not equal to an area of the third light-exiting surface. In greater detail, a total area of the light-exiting surfaces S2 of the green micro LEDs 130 in the green sub-pixel 100G is larger than a total area of the light-exiting surfaces S3 of the blue micro LEDs 140 in the blue sub-pixel 100B. In greater detail, the total area of the light-exiting surfaces S3 of the blue micro LEDs 140, the total area of the light-exiting surfaces S2 of the green micro LEDs 130, and a total area of the light-exiting surfaces S1 of the red micro LEDs 120 according to the present embodiment substantially satisfy the following relation:

AR≧AG≧AB (1)

where AR represents the total area of the light-exiting surfaces S1 of the red micro LEDs 120, AG represents the total area of the light-exiting surfaces S2 of the green micro LEDs 130, and AB represents the total area of the light-exiting surfaces S3 of the blue micro LEDs 140. However, AR, AG, and AB are not the same at the same time. Therefore, since the EQE of the red micro LED 120 is lower and the EQE of the blue micro LED 140 is higher, the total area of the light-exiting surfaces S3 of the blue micro LEDs 140 is smaller and the total area of the light-exiting surfaces S1 of the red micro LEDs 120 is larger in the present embodiment, when only considering the luminous efficiencies of the micro LEDs, so as to compensate for the inferior luminous efficiency of the sub-pixel in a specific color (such as the red sub-pixel 100R).

In greater detail, the total area (AR) of the light-exiting surfaces S1 of the red micro LEDs 120, the total area (AG) of the light-exiting surfaces S2 of the green micro LEDs 130, and the total area (AB) of the light-exiting surfaces S3 of the blue micro LEDs 140 substantially satisfy the following proportions:

AR:AG:AB=10:3:2 (2)

Hence, since the highest EQEs of the red micro LED 120, the green micro LED 130, and the blue micro LED 140 in FIG. 2 are respectively 3%, 10%, and 15%, the sub-pixel having the inferior luminous efficiency can be compensated by adjusting the proportions of the total areas of the light-exiting surfaces S1, S2, S3 when AR:AG:AB=10:3:2 according to the present embodiment. As a result, the inconsistent luminous efficiencies of the sub-pixels of different colors can be improved.

In greater detail, a description is provided with reference to “Table 1”. “Table 1” discloses EQEs of LEDs not been microminiaturized (referred to as LEDs in Table 1) and EQEs of microminiaturized LEDs (referred to as μLEDs in Table 1), and relationships of compensation proportions between total light emitting areas of the LEDs not been microminiaturized and relationships of compensation proportions between total light emitting areas of the microminiaturized LEDs when only considering the luminous efficiencies of the LEDs of different colors. The above LEDs not been microminiaturized refer to an LED having a side length outside 3 to 150 micrometers, for example, a commercially available LED which may have a side length of 1 cm.

TABLE 1

| | Red | Green | Blue |
|---|---|---|---|
| External Quantum Efficiencies | 35% | 50% | 65% |
| (EQEs) of LEDs | | | |
| Compensation Proportions of | 2.86 | 2 | 1.54 |
| Light Emitting Areas of LEDs | | | |
| External Quantum Efficiencies | 3% | 10% | 15% |
| (EQEs) of μLEDs | | | |
| Compensation Proportions of | 10 | 3 | 2 |
| Light Emitting Areas of μLEDs | | | |

In some embodiments, if only considering the luminous efficiencies of the LEDs, the total area of the light-exiting surfaces S1 of the red micro LEDs 120 may be 1 to 35 times the total area of the light-exiting surfaces S2 of the green micro LEDs 130. The total area of the light-exiting surfaces S3 of the blue micro LEDs 140 may be 0.5 to 1 time the total area of the light-exiting surfaces S2 of the green micro LEDs 130. In greater detail, it would be understood from “Table 1” that a range of AR/AG is approximately 1.43 to 3.3 and a range of AB/AG is approximately 0.67 to 0.77 when only considering the luminous efficiencies of the micro LEDs of different colors. In other words, in the embodiment shown in FIG. 6, the total area of the light-exiting surfaces S1 of the red micro LEDs 120 may be 1.43 to 3.3 times the total area of the light-exiting surfaces S2 of the green micro LEDs 130. The total area of the light-exiting surfaces S3 of the blue micro LEDs 140 may be 0.67 to 0.77 times the total area of the light-exiting surfaces S2 of the green micro LEDs 130. Hence, by properly adjusting the magnitude relationships between the total areas of the light-exiting surfaces S1, S2, S3 of the red, green, and blue micro LEDs 120, 130, 140, the inconsistent luminous efficiencies of the sub-pixels of different colors can be improved.

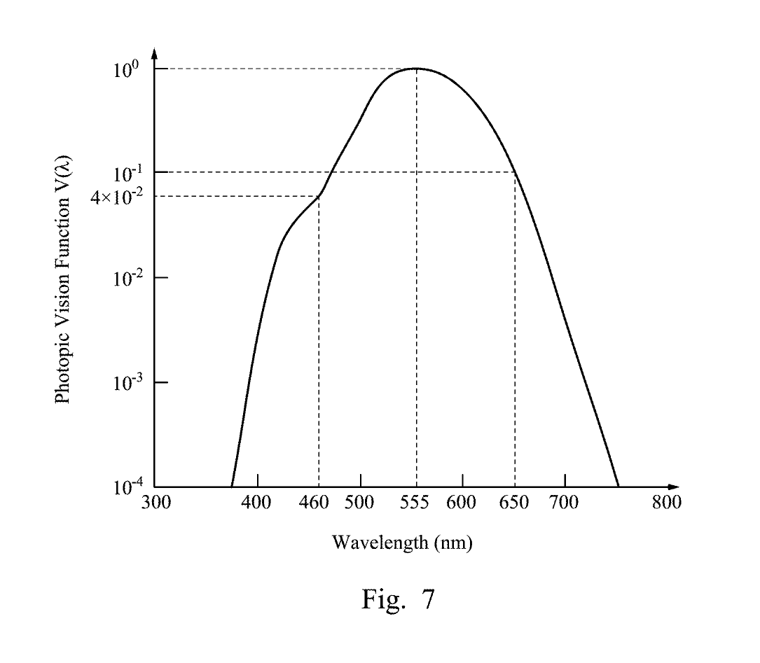

In addition, human eyes have different perception of red light, green light, and blue light. A description is provided with reference to FIG. 7. FIG. 7 depicts a curve illustrating human eye perception to light in different wave bands, where the horizontal axis represents wavelength with the unit nm, the vertical axis represents the photopic vision function V(λ). For example, in a bright environment, human eyes have the most acute perception to 555 nms. Hence, the photopic vision function V(λ) may be a ratio of a radiant energy flux of light having a wavelength of 555 nm to a radiant energy flux of light having any wavelength when a same brightness is generated. As shown in the figure, if the red light is evaluated at a wavelength of 650 nm, the green light is evaluated at a wavelength of 555 nm, and the blue light is evaluated at a wavelength of 460 nm, proportions of human eye perception to red light, green light, and blue light are respectively 0.1:1:0.04, under a same light intensity. In other words, human eyes are more sensitive to light in the green wave band. Hence, in an individual or the single pixel unit 100, when considering the human eye perception to light in different wave bands, the total area of the light-exiting surfaces of the green micro LEDs 130 can be smaller, and the red micro LEDs 120 should have a larger total light emitting area than the green micro LEDs 130. As shown in the embodiment in FIG. 6, since the total area of the light-exiting surfaces S1 of the red micro LEDs 120 is larger than the total area of the light-exiting surfaces S2 of the green micro LEDs 130, the problem that human eyes are not easy to perceive red light is improved.

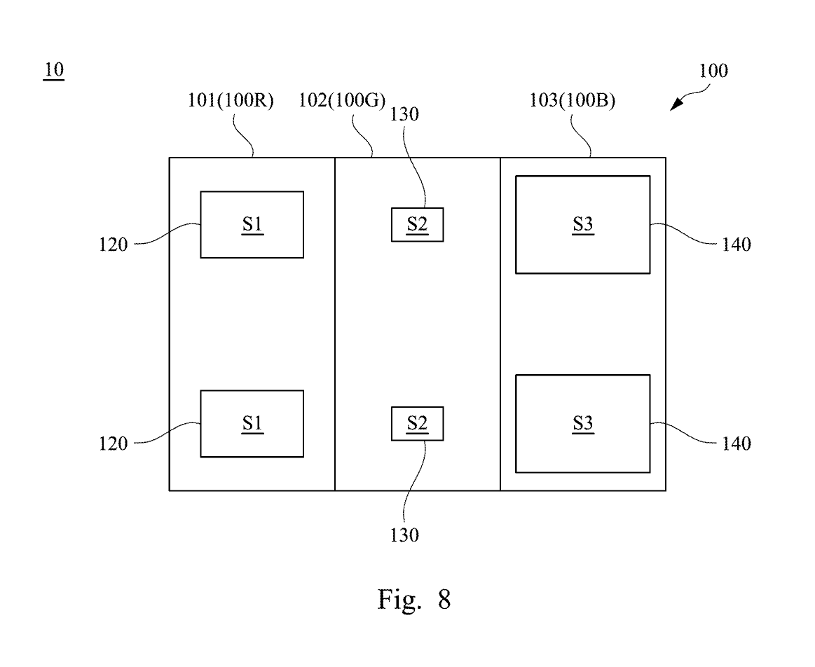

FIG. 8 depicts an enlarged view of the pixel unit 100 of the LED display 10 according to another embodiment of this invention. As shown in the figure, the sub-pixels 101(100R), 102(100G), 103(100B) in the individual pixel unit 100 respectively have the two red micro LEDs 120, the two green micro LEDS 130, and the two blue micro LEDs 140 according to the present embodiment. Additionally, when only considering the human eye perception to light in different wave bands, the total area of the light-exiting surface S3 of the blue micro LEDs 140 is larger than the total area of the light-exiting surface S1 of the red micro LEDs 120 according to the present embodiment. In greater detail, the total area of the light-exiting surfaces S3 of the blue micro LEDs 140, the total area of the light-exiting surfaces S2 of the green micro LEDs 130, and the total area of the light-exiting surfaces S1 of the red micro LEDs 120 substantially satisfy the following relation:

AB≧AR≧AG (3)

As a result, since human eyes are less sensitive to blue light and more sensitive to green light, in the present embodiment the total area of the light-exiting surfaces S3 of the blue micro LEDs 140 is larger and the total area of the light-exiting surfaces S2 of the green micro LEDs 130 is smaller. However, AR, AG, and AB are not the same at the same time. The problem that the human eyes have different perception to light in different wave bands is thus improved.

In greater detail, the total area of the light-exiting surfaces S3 of the blue micro LEDs may be 1 to 20 times the total area of the light-exiting surfaces S2 of the green micro LEDs 130. In another embodiment, the total area of the light-exiting surfaces S3 of the blue micro LEDs 140 may be 16 to 20 times the total area of the light-exiting surface S2 of the green micro LEDs 130. Hence, by properly adjusting the proportional relationships between the total areas of the light-exiting surfaces S1, S2, S3 of the red, green, and blue micro LEDs 120, 130, 140, the problem that human eyes have different perception to light in different wave bands is thus improved.

A description is provided with reference to Table 2. In practical applications, the total area of the light-exiting surfaces S1 of the red micro LEDs 120, the total area of the light-exiting surfaces S2 of the green micro LEDs 130, and the total area of the light-exiting surfaces S3 of the blue micro LEDs 140 substantially satisfy the following proportions:

AR:AG:AB=10:1:25 (4)

Hence, since the proportions of human eye perception to red light, green light, and blue light are respectively 0.1:1:0.04 (see FIG. 7), the human eye perception to red light, green light, and blue light in the pixel unit 100 can be improved when AR:AG:AB=10:1:25 under approximately the same light intensity.

TABLE 2

| | Red | Green | Blue |
|---|---|---|---|
| Human Eye Perception | 0.1 | 1 | 0.04 |
| Compensation Proportions | 10 | 1 | 25 |
| for Human Eye Perception | | | |

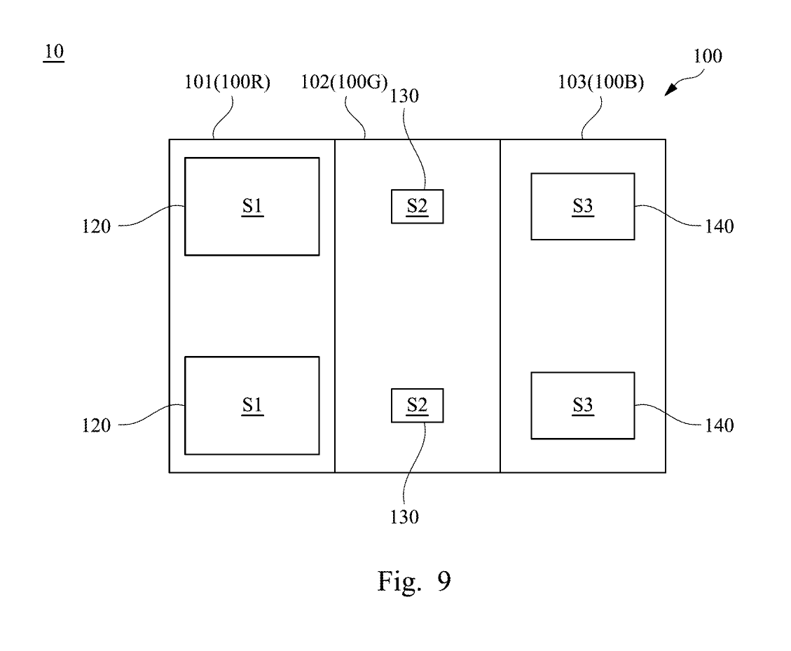

FIG. 9 depicts an enlarged view of the pixel unit 100 of the LED display 10 according to still another embodiment of this invention. As shown in the figure, the sub-pixels 101(100R), 102(100G), 103(100B) in the individual pixel unit 100 respectively have the two red micro LEDs 120, the two green micro LEDS 130, and the two blue micro LEDs 140 according to the present embodiment. In the present embodiment, both the luminous efficiencies of the micro LEDs and the human eye perception to light of different colors are considered to adjust magnitude relationships between the total areas of the micro LEDs of different colors. The total area of the light-exiting surfaces S3 of the blue micro LEDs 140 is smaller than the total area of the light-exiting surfaces S1 of the red micro LEDs 120 and larger than the total area of the light-exiting surfaces S2 of the green micro LEDs 130 according to the present embodiment. In brief, the total area of the light-exiting surfaces S3 of the blue micro LEDs 140, the total area of the light-exiting surfaces S2 of the green micro LEDs 130, and the total area of the light-exiting surfaces S1 of the red micro LEDs 120 according to the present embodiment substantially satisfy the following relation:

AR≧AB≧AG (5)

As a result, since both the luminous efficiencies of the micro LEDs and the human eye perception to light of different colors are considered, the magnitude relationships between the total areas according to the present embodiment can compensate for the sub-pixel having the inferior luminous efficiency. However, AR, AG, and AB are not the same at the same time. The problem that human eyes have different perception to light in different wave bands can also be improved.

In greater detail, the total area (AR) of the light-exiting surfaces S1 of the red micro LEDs 120, the total area (AG) of the light-exiting surfaces S2 of the green LEDs 130, and the total area (AB) of the light-exiting surfaces S3 of the blue LEDs 140 substantially satisfy:

AR:AG:AB=100:3:50 (6)

Proportional relationships in (6) according to the present embodiment can be obtained by multiplying the proportional relationships in (2) and the proportional relationships in (4). Hence, in the present embodiment since the EQE of the red micro LED 120 is lower and human eyes have a poorer perception to red light, the total area of the light-exiting surfaces S1 of the red micro LEDs 120 obtains a larger compensation. Conversely, since human eyes are more sensitive to green light and the EQE of green light is at least higher than that of red light, the total area compensation obtained by green light is smaller. As a result, the present embodiment is able to improve the inconsistent luminous efficiencies of sub-pixels of different colors and the problem that human eyes have different perception to light in different wave bands at the same time.

Next, a description is provided with reference to “Table 3”. In addition to information in “Table 1”, “Table 3” contains proportions of human eye perception to light of different colors in “Table 2”, compensation proportions of light emitting areas of micro LEDs (referred to as μLEDs in Table 3) and LEDs not been microminiaturized (referred to as LEDs in Table 3) when only considering human eye perception, and compensation proportions of light emitting areas of the micro LEDs (referred to as μLEDs in Table 3) and the LEDs not been microminiaturized (referred to as LEDs in Table 3) when considering both the luminous efficiencies of the LEDs and human eye perception.

TABLE 3

| | Red | Green | Blue |
|---|---|---|---|
| Compensation Proportions of Light | 2.86 | 2 | 1.54 |
| Emitting Areas of LEDs (When Only | | | |
| Considering EQEs) | | | |
| Compensation Proportions of Light | 10 | 3 | 2 |
| Emitting Areas of μLEDs (When Only | | | |
| Considering EQEs) | | | |
| Compensation Proportions for Human | 10 | 1 | 25 |
| Eye Perception | | | |
| Compensation Proportions of Light | 28.6 | 2 | 38.5 |
| Emitting Areas of LEDs (When | | | |
| Considering EQEs and Human Eye | | | |
| Perception) | | | |
| Compensation Proportions of Light | 14.3 | 1 | 19.25 |
| Emitting Areas of LEDs (When | | | |
| Considering EQEs and Human Eye | | | |
| Perception) | | | |
| Compensation Proportions of Light | 100 | 3 | 50 |
| Emitting Areas of μLEDs (When | | | |
| Considering EQEs and Human Eye | | | |
| Perception) | | | |
| Compensation Proportions of Light | 33.33 | 1 | 16.67 |
| Emitting Areas of μLEDs (When | | | |
| Considering EQEs and Human Eye | | | |
| Perception) | | | |

In some embodiments, after considering both the luminous efficiencies of the LEDs and human eye perception, the total area of the light-exiting surfaces S1 of the red micro LEDs 120 may be 14 to 34 times the total area of the light-exiting surfaces S2 of the green micro LEDs 130. The total area of the light-exiting surfaces S3 of the blue micro LEDs 140 may be 16 to 20 times the total area of the light-exiting surfaces S2 of the green micro LEDs 130. In greater detail, a description is provided with reference to “Table 3”. The total area of the light-exiting surfaces S1 of the red micro LEDs 120 may be 14.3 to 33.3 times the total area of the light-exiting surfaces S2 of the green micro LEDs 130. The total area of the light-exiting surfaces S3 of the blue micro LEDs 140 may be 16.67 to 19.25 times the total area of the light-exiting surfaces S2 of the green micro LEDs 130. Thus, by properly adjusting the magnitude relationships between the total areas of the light-exiting surfaces S1, S2, S3 of the red, green, and blue micro LEDs 120, 130, 140, the inconsistent luminous efficiencies of the sub-pixels of different colors and the problem that human eyes have different perception to light in different wave bands can be improved at the same time.

In addition, in the above one or more embodiments, the total area of the light-exiting surfaces S1 of the red micro LEDs 120, the total area of the light-exiting surfaces S2 of the green micro LEDs 130, and the total area of the light-exiting surfaces S3 of the blue micro LEDs 140 substantially satisfy the following relation:

Amin<Amax<35*Amin (7)

Where Amin is a minimum in the total area of the light-exiting surfaces S1 of the red micro LEDs 120, the total area of the light-exiting surfaces S2 of the green micro LEDs 130, and the total area of the light-exiting surfaces S3 of the blue LEDs 140, Amax is a maximum in the total area of the light-exiting surfaces S1 of the red micro LEDs 120, the total area of the light-exiting surfaces S2 of the green micro LEDs 130, and the total area of the light-exiting surfaces S3 of the blue LEDs 140. For example, in the embodiment shown in FIG. 9, the total area of the light-exiting surfaces S1 of the red micro LEDs 120 is smaller than 35 times the total area of the light-exiting surfaces S2 of the green micro LEDs 130.

It would be understood that those of ordinary skill in the art may dispose different numbers of the red micro LEDs 120, the green micro LEDs 130, and the blue micro LEDs 140 to realize the proportional relationships or magnitude relationships between areas according to the above one or more embodiments. Additionally, in the embodiments shown in FIG. 6 to FIG. 9, the light-exiting surfaces S1, S2, S3 of the red micro LEDs 120, the green micro LEDs 130, and the blue micro LEDs 140 are depicts as rectangles, but the disclosure is not limited in this regard. The light-exiting surfaces S1, S2, S3 of the red micro LEDs 120, the green micro LEDs 130, and the blue micro LEDs 140 may be in any shape once the proportional relationships or magnitude relationships between areas according to the above one or more embodiments are satisfied.

In addition to that, the above embodiments all discuss the magnitude relationships or proportional relationships between the total areas of the light-exiting surfaces of the micro LEDs in the sub-pixels of different colors. It would be understood that, in practical applications, an area percentage of each of the sub-pixels occupied by the total area of the light-exiting surfaces of all micro LEDs in the each of the sub-pixels should be within a predetermined range in view of the limitations of process capability. A description is provided with reference to “Table 4”. Table 4 shows area percentages of the red, green, or blue sub-pixels 100R, 100G, 100B respectively occupied by the total areas of the light-exiting surfaces of the red, green, or blue micro LEDs 120, 130, 140 according to one embodiment. An area of individual sub-pixels in Table 4 is approximately 99 micrometers multiplied by 33 micrometers. In consideration of the upper limit of process capability, a minimum side length of the micro LEDs is approximately 3 micrometers (an area of individual micro LEDs is 3 micrometers multiplied by 3 micrometers), and a maximum side length of the micro LEDs is 20 micrometers (the area of individual micro LEDs is 20 micrometers multiplied by 20 micrometers). In addition, a number of the micro LEDs in each of the sub-pixels is 1 to 2.

TABLE 4

| Area Of | Area of an | Total Area of | |
|---|---|---|---|
| Sub-pixel | Individual | Light-exiting | |
| (μm\hat{ }2) | Micro LED | surface(s) | Percentage |
| 99*33(um\hat{ }2) | 3*3(um\hat{ }2) | 9*1(One) | 0.3% |
| 99*33(um\hat{ }2) | 10*10(um\hat{ }2) | 100*2(Two) | 6.0% |
| 99*33(um\hat{ }2) | 16*16(um\hat{ }2) | 256*2(Two) | 15.7% |
| 99*33(um\hat{ }2) | 20*20(um\hat{ }2) | 400*2(Two) | 24.5% |

As shown in “Table 4”, in one embodiment, the area percentage of each of the sub-pixels occupied by the total area of the light-exiting surfaces of the all micro LEDs in the each of the sub-pixels is approximately 0.3% to 24.5%, but the disclosure is not limited in this regard. In other embodiments, the area of the sub-pixels my be larger than or smaller than 99 micrometers multiplied by 33 micrometers, and the side length of the micro LEDs may be up to 150 micrometers. The number of the micro LEDs in each of the sub-pixels is not limited to 1 to 2. Hence, in other embodiments, the area percentage of the each of the sub-pixels occupied by the total area of the light-exiting surfaces of the all micro LEDs in the each of the sub-pixels may be outside 0.3% to 24.5%, such as from 0.3% to 30%.

In summary, the above embodiments can adjust the relationships between the total areas of the red, green, and blue micro LEDs 120, 130, 140 in the red, green, and blue sub-pixels 100R, 100G, 100B to improve the inconsistent luminous efficiencies of the sub-pixels of different colors and the problem that human eyes have different perception to light in different wave bands. As a result, brightness of the red micro LEDs 120, the green micro LEDs 130, or the blue micro LEDs 140, whose total area of light-exiting surfaces is the largest of the total areas of the light-exiting surfaces S1, S2, S3, is greater than or equal to brightness of the red micro LEDs 120, the green micro LEDs 130, or the blue micro LEDs 140, whose total area of the light-exiting surfaces is the smallest of the total areas of the light-exiting surfaces S1, S2, S3 in each of the pixel units 100.

A manufacturing method of the LED display 10 is further disclosed in the following embodiment to facilitate understanding. A description is provided with reference to FIG. 3 and FIG. 4. The manufacturing method of the LED display 10 may comprise the following steps:

S1: providing a substrate 110. As shown in FIG. 3, the substrate 110 may comprise at least one pixel unit 100, and the substrate 110 may be an active device array substrate.

S2: disposing at least one red micro LED 120 in the pixel unit 100 to form a red sub-pixel 100R, disposing at least one green micro LED 130 in the pixel unit 100 to form a green sub-pixel 100G, and disposing at least one blue micro LED 140 in the pixel unit 100 to form a blue sub-pixel 100B. The red sub-pixel 100R, the green sub-pixel 100G, and the blue sub-pixel 100B are located in the pixel unit 100. In greater detail, the red, green, and blue micro LEDs 120, 130, 140 can be transposed from another substrate (not show in figure) to the pixel unit 100 of the substrate 110 by utilizing a micromechanical device. Numbers of the red, green, and blue micro LEDs 120, 130, 140 disposed may be one or more than one depending on a size of light-exiting surfaces S1, S2, S3 as required.

In one embodiment, the step of providing the substrate 110 further comprises:

S1.1: forming pixel circuits T1, T2, T3. The pixel circuits T1, T2, T3 are located in the pixel unit 100. Each of the pixel circuits T1, T2, T3 may comprise a transistor, a data line, or a scan line, etc., and the pixel circuits T1, T2, T3 may be configured to respectively drive the luminescence of the red, green, and blue micro LEDs 120, 130, 140.

S2.1: forming an insulating layer 150 on the pixel circuits T1, T2, T3. In greater detail, the insulating layer 150 covers the pixel circuits T1, T2, T3, and the insulating layer 150 may have a plurality of through holes TH1, TH2, TH3. The red, green, and blue micro LEDs 120, 130, 140 can be electrically connected to the pixel circuits T1, T2, T3 via the through holes TH1, TH2, TH3.

S1.3: forming a pixel define layer 160 on top of the insulating layer 150. A plurality of openings O1, O2, O3 may be defined in the pixel define layer 160 by utilizing lithography and etching processes.

S1.4: forming first electrodes 171, 172, 173 in the openings O1, O2, O3, respectively. The first electrodes 171, 172, 173 may be electrically connected to the pixel circuits T1, T2, T3 via the through holes TH1, TH2, TH3, respectively. The first electrodes 171, 172, 173 are electrically connected to one terminal of the red micro LED 120, one terminal of the green micro LED 130, and one terminal of the blue micro LED 140, and the first electrodes 171, 172, 173 may be made of a high reflective metal material for reflecting light. In one embodiment, electrical adhesive layers 191, 192, 193 are respectively disposed on the first electrodes 171, 172, 173 in the openings O1, O2, O3. For example, each of the electrical adhesive layers 191, 192, 193 may be conductive adhesive or other suitable conductive materials. The conductive material may be, for example, at least one of indium (In), bismuth (Bi), tin (Sn), silver (Ag), gold (Au), copper (Cu), gallium (Ga) and antimony (Sb), but the disclosure is not limited in this regard. The electrical adhesive layers 191, 192, 193 are configured to fix the red, green, and blue micro LEDs 120, 130, 140 in the openings O1, O2, O3, and electrically connect the first electrode 171, 172, 173.

S1.5: forming a second electrode 180. The second electrode 180 may be a transparent electrode for electrically connecting another terminal of the red micro LED 120, another terminal of the green micro LED 130, and another terminal of the blue micro LED 140.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode (LED) display comprising:
at least one pixel unit having a plurality of sub-pixels disposed on a substrate;
the plurality of sub-pixels comprising:
a red sub-pixel comprising at least one red micro LED;
a green sub-pixel comprising at least one green micro LED; and
a blue sub-pixel comprising at least one blue micro LED, and the red sub-pixel, the green sub-pixel, and the blue sub-pixel being located in the pixel unit, wherein each of the at least one red micro LED, the at least one green micro LED, and the at least one blue micro LED comprises:
a first type semiconductor layer, a second type semiconductor layer, and an active layer disposed between the first type semiconductor layer and the second type semiconductor layer, each of the at least one red micro LED, the at least one green micro LED, and the at least one blue micro LED having a light-exiting surface, wherein a total area of the light-exiting surface of the at least one red micro LED is larger than a total area of the light-exiting surface of the at least one green micro LED; and
two electrodes disposed in each of the red sub-pixel, the green sub-pixel, and the blue sub-pixel, wherein one of the two electrodes is electrically connected with the corresponding first type semiconductor layer, the other one of the two electrodes is electrically connected with the second type semiconductor layer, and at least one of the two electrodes is electronically connected with a corresponding thin film transistor.

2. The LED display of claim 1, wherein a total area of the light-exiting surface of the at least one blue micro LED is larger than the total area of the light-exiting surface of the at least one red micro LED.

3. The LED display of claim 1, wherein an area percentage of the red sub-pixel, the green sub-pixel, or the blue sub-pixel respectively occupied by the total area of the light-exiting surface of the at least one red micro LED, the total area of the light-exiting surface of the at least one green LED, or a total area of the light-exiting surface of the at least one blue micro LED is substantially from 0.3% to 30%.

4. The LED display of claim 1, wherein the total area of the light-exiting surface of the at least one red micro LED, the total area of the light-exiting surface of the at least one green micro LED, and a total area of the light-exiting surface of the at least one blue micro LED in an individual pixel unit substantially satisfy:
AR:AG:AB=10:1:25,
where AR is the total area of the light-exiting surface of the at least one red micro LED, AG is the total area of the light-exiting surface of the at least one green micro LED, AB is the total area of the light-exiting surface of the at least one blue micro LED.

5. The LED display of claim 1, wherein the total area of the light-exiting surface of the at least one green micro LED is larger than a total area of the light-exiting surface of the at least one blue micro LED.

6. The LED display of claim 1, wherein the total area of the light-exiting surface of the at least one red micro LED, the total area of the light-exiting surface of the at least one green micro LED, and a total area of the light-exiting surface of the at least one blue micro LED in an individual pixel unit substantially satisfy:
AR:AG:AB=10:3:2,
where AR is the total area of the light-exiting surface of the at least one red micro LED, AG is the total area of the light-exiting surface of the at least one green micro LED, AB is the total area of the light-exiting surface of the at least one blue micro LED.

7. The LED display of claim 1, wherein in an individual pixel unit the total area of the light-exiting surface of the red micro LED is 1.0 to 35 times the total area of the light-exiting surface of the green micro LED, and a total area of the light-exiting surface of the blue micro LED is substantially 0.5 to 20 times the total area of the light-exiting surface of the green micro LED.

8. The LED display of claim 1, wherein in an individual pixel unit the total area of the light-exiting surface of the red micro LED is 14 to 34 times the total area of the light-exiting surface of the green micro LED, a total area of the light-exiting surface of the blue micro LED is substantially 16 to 20 times the total area of the light-exiting surface of the green micro LED.

9. The LED display of claim 1, wherein the total area of the light-exiting surface of the red micro LED, the total area of the light-exiting surface of the green micro LED, and a total area of the light-exiting surface of the blue micro LED in an individual pixel unit substantially satisfy:
AR:AG:AB=100:3:50,
where AR is the total area of the light-exiting surface of the red micro LED, AG is the total area of the light-exiting surface of the green micro LED, AB is the total area of the light-exiting surface of the blue micro LED.

10. The LED display of claim 1, wherein at least one of numbers of the at least one red micro LED, the at least one green micro LED, and the at least one blue LED respectively in the red sub-pixel, the green sub-pixel, and the blue sub-pixel is plural.

11. The LED display of claim 1, wherein the total area of the light-exiting surface of the red micro LED, the total area of the light-exiting surface of the green micro LED, and a total area of the light-exiting surface of the blue micro LED substantially satisfy:
Amin<Amax<35*Amin,
where Amin is a minimum in the total area of the light-exiting surface of the red micro LED, the total area of the light-exiting surface of the green micro LED, and the total area of the light-exiting surface of the blue LED, Amax is a maximum in the total area of the light-exiting surface of the red micro LED, the total area of the light-exiting surface of the green micro LED, and the total area of the light-exiting surface of the blue micro LED.

12. The LED display of claim 1, wherein the substrate comprises:
an insulating layer covering the thin film transistor in each of the red sub-pixel, the green sub-pixel, and the blue sub-pixel, the insulating layer having a plurality of through holes, and at least one of the two electrodes is electronically connected with the corresponding thin film transistor by one of the plurality of through holes.

13. The LED display of claim 12, further comprising:
a pixel define layer on top of the insulating layer, and the pixel define layer comprising a plurality of openings, wherein the two electrodes are located in the openings.

14. The LED display of claim 1, wherein a number of the at least one red micro LED, the at least one green micro LED, or the at least one blue micro LED respectively in the red sub-pixel, the green sub-pixel or the blue sub-pixel is plural.

15. The LED display of claim 1, wherein the at least one red micro LED in the red sub-pixel is plural.

16. A manufacturing method of a light emitting diode (LED) display comprising:
providing a substrate, the substrate comprising at least one pixel unit;
transferring at least one red micro LED from an another substrate to the substrate, and disposing the at least one red micro LED in the pixel unit to form a red sub-pixel;
transferring at least one green micro LED from the another substrate to the substrate, and disposing the at least one green micro LED in the pixel unit to form a green sub-pixel; and
transferring at least one blue micro LED from the another substrate to the substrate, and disposing the at least one blue micro LED in the pixel unit to form a blue sub-pixel, and the red sub-pixel, the green sub-pixel, and the blue sub-pixel being located in the pixel unit, wherein a total area of a light-exiting surface of the red micro LED is larger than a total area of a light-exiting surface of the green micro LED.

17. The manufacturing method of the LED display of claim 16, wherein the step of providing the substrate further comprises:
forming a pixel circuit located in the pixel unit;
forming an insulating layer on the pixel circuit;
forming a pixel define layer on top of the insulating layer, and forming at least one opening in the pixel define layer;
forming a first electrode in the opening and the first electrode being electrically connected to the pixel circuit, the first electrode being electrically connected to one terminal of at least one of the red micro LED, the green micro LED, and the blue micro LED; and
forming a second electrode electrically connected to one terminal of at least one of the red micro LED, the green micro LED, and the blue micro LED.
